(19) United States
(12) Patent Application Publication
(10) Pub. No.: US 2016/0183381 A1
(43) Pub. Date: Jun. 23, 2016

(54) Electronic Component and Overmolding Process

(71) Applicant: Tyco Electronics Corporation, Berwyn, PA (US)

(72) Inventors: Bruce Foster Bishop, Aptos, CA (US); Ronald W. Brennian, JR., Hummelstown, PA (US); Michael A. Oar, San Francisco, CA (US); Leonard Henry Radzilowski, Palo Alto, CA (US)

(73) Assignee: Tyco Electronics Corporation, Berwyn, PA (US)

(21) Appl. No.: 14/581,679

(22) Filed: Dec. 23, 2014

(51) Int. Cl. H05K 3/28; H05K 1/02; H05K 3/10; H05K 1/09

(52) U.S. Cl. CPC H05K 3/28; H05K 1/097; H05K 1/0216; H05K 3/10; H05K 2201/068; H05K 2201/10098; H05K 2201/10151

(57) ABSTRACT

Electronic components and overmolding processes are disclosed. The electronic component, such as, an antenna, includes a substrate, an overmolding bonded to at least a portion of the substrate, the overmolding being a non-planar arrangement of a polymeric material, and a conductive ink positioned on the substrate between the substrate and the overmolding. The conductive ink is devoid or substantially devoid of delamination or fracture from the bonding of the overmolding to the substrate. The overmolding process includes providing a substrate, applying a conductive ink onto the substrate, and bonding an overmolding to at least a portion of the substrate, the overmolding being an arrangement of a polymeric material. The conductive ink is devoid or substantially devoid of delamination or fracture through the bonding of the overmolding to the substrate.

### FIELD OF THE INVENTION

The present invention is directed to electronic components and overmolding processes. More particularly, the present invention is directed to electronic components with similar coefficients of thermal expansion.

### BACKGROUND OF THE INVENTION

The manufacture of electronic components is constantly being subjected to a need to improve quality, decrease cost, and permit greater complexity. However, many processes for producing higher quality electronic components are cost prohibitive. Likewise, producing complex designs can be cost prohibitive. Using lower cost processes seems desirable, but often can result in lower quality or limitations on complexity, which can be undesirable.

One relatively known low cost process for producing components is overmolding. Overmolding involves heating materials to temperatures of up to 300° C. Such temperatures are not conducive for numerous materials and can cause fracture, delamination, or other detrimental effects on materials. As such, use of overmolding has been limited to materials resistant to high temperatures or materials that are not at risk of fracture, delamination, distortion, damage, or other detrimental effects.

Many known conductive traces are limited in temperature resistance. High temperatures can cause such conductive traces to fracture or delaminate from substrates. As such, conductive traces have previously been perceived as incompatible with overmolding. For example, attempts to overmold 2-shot molded devices and laser direct structured devices have been unsuccessful due to the base materials not being compatible with the high temperatures of overmolding.

Additive or three-dimensional manufacturing processes provide low cost techniques for producing relatively complex components. However, such techniques can suffer from other drawbacks, such as, a lack of homogeneity, production of seam lines or striations, and creation of additional fracture points.

Electronic components and overmolding processes that show one or more improvements in comparison to the prior art would be desirable in the art.

### BRIEF DESCRIPTION OF THE INVENTION

In an embodiment, an electronic component includes a substrate, an overmolding bonded to at least a portion of the substrate, the overmolding being a non-planar arrangement of a polymeric material, and a conductive ink positioned on the substrate between the substrate and the overmolding. The conductive ink is devoid or substantially devoid of delamination or fracture from the bonding of the overmolding to the substrate.

In another embodiment, an antenna includes a substrate, an overmolding bonded to at least a portion of the substrate, and a conductive ink positioned on the substrate and between the substrate and the overmolding in a non-planar arrangement. The overmolding is an arrangement of a polymeric material.

In another embodiment, an overmolding process includes providing a substrate, applying a conductive ink onto the substrate, and bonding an overmolding to at least a portion of the substrate, the overmolding being an arrangement of a polymeric material. The conductive ink is devoid or substantially devoid of delamination or fracture through the bonding of the overmolding to the substrate.

Other features and advantages of the present invention will be apparent from the following more detailed description, taken in conjunction with the accompanying drawings which illustrate, by way of example, the principles of the invention.

### BRIEF DESCRIPTION OF THE DRAWINGS

FIG. 1 is a perspective view of an electronic component having an overmolding bonded to a substrate with a conductive ink enclosed within, according to the disclosure.

Wherever possible, the same reference numbers will be used throughout the drawings to represent the same parts.

### DETAILED DESCRIPTION OF THE INVENTION

Provided are electronic components and overmolding processes. Embodiments of the present disclosure, for example, in comparison to concepts failing to include one or more of the features disclosed herein, permit conductive traces to be applied with an overmolding, reduce or eliminate fracture or delamination of conductive traces, permit use of non-planar arrangements of overmoldings and/or conductive traces, permit production of components having homogeneous overmoldings, permit components to have fewer or no seam lines or striations, permit components to have fewer or no fracture points, permit microstructure orientation within components, or permit any suitable combination thereof.

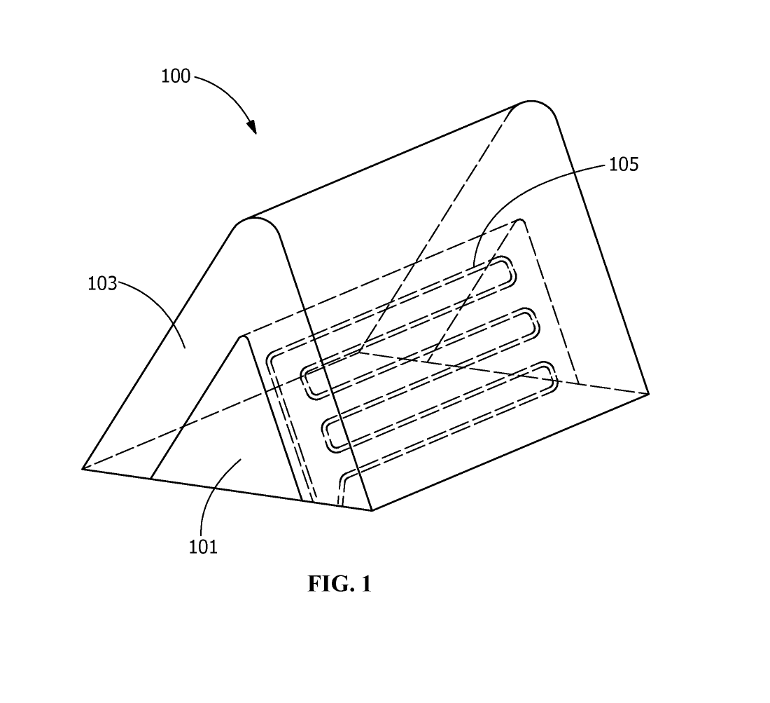

FIG. 1 shows an electronic component 100, such as, an antenna, a sensor, a medical device, an implant, automotive paneling, electromagnetic interference shielding, or a combination thereof. The electronic component 100 includes a substrate 101, an overmolding 103 bonded to at least a portion of the substrate 101, and a conductive ink 105 (for example, arranged as a conductive trace and/or being sintered and/or non-sintered, such as being thermoplastic or thermoset) positioned on the substrate 101 between the substrate 101 and the overmolding 103.

The overmolding 103 is an arrangement (for example, a non-planar arrangement) of a polymeric and/or elastomeric material. The overmolding extends over and around the substrate 101, for example, in at least three planes. In one embodiment, the overmolding 103 and the substrate 101 seal the conductive ink 105. The sealing of the conductive ink 105 creates an air-tight, waterproof, water-resistant, dark, or otherwise completely contained or partially contained arrangement.

The overmolding process causes the overmolding 103 and the substrate 101 to expand when heating and/or shrink after heating to the overmolding temperature, thereby creating thermal expansion and contraction conditions. The conductive ink 105 is devoid or substantially devoid of delamination or fracture from the bonding of the overmolding 103 to the substrate 101, for example, due to the coefficients of thermal expansion (CTEs) being comparatively similar. For example, during the overmolding process, the conductive ink 105, the substrate 101, and the overmolding 103 are subjected to a significant temperature change.

According to the disclosure, the conductive ink 105 does not delaminate from the substrate 101 or fracture throughout the temperature change. Suitable temperature changes include, but are not limited to, increasing from room temperature (23° C.) to an overmolding temperature (up to 300° C.) and decreasing back to room temperature (23° C.), increasing by over 100° C., increasing by over 200° C., increasing by over 250° C., decreasing by over 100° C., decreasing by over 200° C., decreasing by over 250° C., or any suitable combination, sub-combination, range, or sub-range therein.

In one embodiment, the coefficient of thermal expansion (CTE) of the overmolding 103 is within 5% of the CTE of the conductive ink 105. In a further embodiment, the difference between the CTE of the overmolding 103 and the CTE of the conductive ink 105 is less than 3%, less than 2%, less than 1%, or any suitable combination, sub-combination, range, or sub-range therein.

Additionally or alternatively, in one embodiment, the CTE of the conductive ink 105 is within 5% of the CTE of the substrate 101. In a further embodiment, the difference between the CTE of the conductive ink 105 and the CTE of the substrate 101 is less than 3%, less than 2%, less than 1%, or any suitable combination, sub-combination, range, or sub-range therein.

Additionally or alternatively, in one embodiment, the CTE of the overmolding 103 is within 5% of the CTE of the substrate 101. In a further embodiment, the difference between the CTE of the overmolding 103 and the CTE of the substrate 101 is less than 3%, less than 2%, less than 1%, or any suitable combination, sub-combination, range, or sub-range therein.

Suitable CTEs for the substrate 101, the overmolding 103, and/or the conductive ink 105 include, but are not limited to, being between 15 ppm/° C. and 45 ppm/° C. (for example, below a temperature of 147° C.), being between 25 ppm/° C. and 45 ppm/° C. (for example, below a temperature of 147° C.), being between 30 ppm/° C. and 40 ppm/° C. (for example, below a temperature of 147° C.), being between 35 ppm/° C. and 40 ppm/° C. (for example, below a temperature of 147° C.), being between 30 ppm/° C. and 35 ppm/° C. (for example, below a temperature of 147° C.), or any suitable combination, sub-combination, range, or sub-range therein.

The overmolding 103 is or includes any suitable material capable of withstanding the temperatures of the overmolding process and being bonded with the substrate 101. In one embodiment, the material of the overmolding is a polymeric material, for example, polycarbonate, with glass blended within, for example, at a concentration, by volume, of between 20% and 40%, between 20% and 35%, between 25% and 40%, between 25% and 35%, between 35% and 40%, or any suitable combination, sub-combination, range, or sub-range therein.

The conductive ink 105 is or includes any suitable conductive trace material. One suitable material is silver conductive epoxy ink. Another suitable material includes a metal nanostructure, an organic solvent, and a capping agent.

The metal nanostructure is or includes, for example, copper, silver, annealed silver, gold, aluminum, alloys thereof, and combinations thereof. Suitable morphologies of the nanostructure include, but are not limited to, having flakes, dendrites, spheres, granules, or combinations thereof.

The organic solvent is or includes, for example, ethanol, isopropyl alcohol, methanol, any other solvent compatible with the metal nanostructure, or a combination thereof. Other suitable organic solvents is or include organic ethers and organic esters, such as butyl diglycol ether.

The capping agent is or includes, for example, poly(vinylpyrrolidone) (PVP), polyaniline (PAN), L-cysteine (L-cys), oleic acid (OA), any other capping agent compatible with the solvent, or a combination thereof.

The substrate 101 is or includes a polymeric material (for example, polycarbonate materials, polyamide materials), or any other suitable material capable of receiving the conductive ink 105.

The conductive ink 105 is positioned on the non-planar region extending a depth from the substrate 101 that provides the desired conductivity for the specific application of use. Suitable depths include, but are not limited to, between 6 and 100 micrometers, between 6 and 20 micrometers, between 8 to 10 micrometers, between 10 to 20 micrometers, between 20 and 60 micrometers, between 60 and 100 micrometers, or any suitable combination, sub-combination, range, or sub range therein.

The trace width of the conductive ink 105 similarly is any width that provides the desired conductivity for the specific application of use. Suitable widths include, but are not limited to, between 10 to 14 micrometers, between 16 to 20 micrometers, between 0.5 millimeter and 1 millimeter, between 0.5 millimeter and 2 millimeters, or any suitable combination, sub-combination, range, or sub range therein.

The mean surface roughness of the conductive ink 105 is any suitable value sufficiently low enough for the specific application of use. Suitable mean surface roughness values include, but are not limited to, less than 10 micrometers, less than 7 micrometers, less than 5 micrometers, less than 3 micrometers, less than 1 micrometer, less than 0.6 micrometer, between 0.1 micrometer and 1 micrometer, or any suitable combination, sub-combination, range, or sub range therein.

The resistance of the conductive ink 105 is any suitable value sufficiently low enough for the specific application of use. Suitable resistance values include, but are not limited to, less than 3 ohms/square, less than 1 ohms/square, less than 0.5 ohms/square, less than 0.02 ohms/square, or any suitable combination, sub-combination, range, or sub range therein.

While the invention has been described with reference to one or more embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims. In addition, all numerical values identified in the detailed description shall be interpreted as though the precise and approximate values are both expressly identified.

What is claimed is:

1. An electronic component, comprising:
a substrate;
an overmolding bonded to at least a portion of the substrate, the overmolding being a non-planar arrangement of a polymeric material; and
a conductive ink positioned on the substrate between the substrate and the overmolding;
wherein the conductive ink is devoid or substantially devoid of delamination or fracture from the bonding of the overmolding to the substrate.

2. The electronic component of claim 1, wherein the conductive ink is positioned in a non-planar arrangement.

3. The electronic component of claim 1, wherein the conductive ink is completely sealed at least partially by the substrate and the overmolding.

4. The electronic component of claim 1, wherein the overmolding extends around the substrate in at least three planes.

5. The electronic component of claim 1, wherein the coefficient of thermal expansion of the overmolding is within 5% of the coefficient of thermal expansion of the substrate.

6. The electronic component of claim 1, wherein the coefficient of thermal expansion of the overmolding is within 1% of the coefficient of thermal expansion of the substrate.

7. The electronic component of claim 1, wherein the coefficient of thermal expansion of the overmolding is within 5% of the coefficient of thermal expansion of the conductive ink.

8. The electronic component of claim 1, wherein the coefficient of thermal expansion of the overmolding is within 1% of the coefficient of thermal expansion of the conductive ink.

9. The electronic component of claim 1, wherein the coefficient of thermal expansion of the conductive ink is within 5% of the coefficient of thermal expansion of the substrate.

10. The electronic component of claim 1, wherein the coefficient of thermal expansion of the conductive ink is within 1% of the coefficient of thermal expansion of the substrate.

11. The electronic component of claim 1, wherein the coefficients of thermal expansion of the conductive ink, the overmolding, and the substrate are between 25 ppm/° C. and 45 ppm/° C. below a temperature of 147° C.

12. The electronic component of claim 1, wherein the component is selected from the group consisting of an antenna, a sensor, a medical device, an implant, automotive paneling, electromagnetic interference shielding, and combinations thereof.

13. The electronic component of claim 1, wherein the component is a touch-sensor.

14. The electronic component of claim 1, wherein the component is an antenna.

15. The electronic component of claim 1, wherein the component is a signal-carrying device.

16. The electronic component of claim 1, wherein the component is a current-carrying device.

17. The electronic component of claim 1, wherein the conductive ink is silver conductive epoxy ink.

18. The electronic component of claim 1, wherein the conductive ink includes a metal nanostructure, an organic solvent, and a capping agent.

19. An antenna, comprising:
a substrate;
an overmolding bonded to at least a portion of the substrate, the overmolding being an arrangement of a polymeric material; and
a conductive ink positioned on the substrate and between the substrate and the overmolding in a non-planar arrangement.

20. An overmolding process, comprising:
providing a substrate;
applying a conductive ink onto the substrate; and
bonding an overmolding to at least a portion of the substrate, the overmolding being an arrangement of a polymeric material;
wherein the conductive ink is devoid or substantially devoid of delamination or fracture through the bonding of the overmolding to the substrate.
